(19) United States
(12) Patent Application Publication
(10) Pub. No.: US 2021/0286256 A1
(43) Pub. Date: Sep. 16, 2021

(54) Mask, Layout, And Lithography System And Lithography Process Of The Same

(71) Applicant: Shanghai Huahong Grace Semiconductor Manufacturing Corporation, Shanghai (CN)

(72) Inventor: Weifeng LI, Shanghai (CN)

(73) Assignee: Shanghai Huahong Grace Semiconductor Manufacturing Corporation, Shanghai (CN)

(21) Appl. No.: 16/878,465

(22) Filed: May 19, 2020

(30) Foreign Application Priority Data
Mar. 10, 2020 (CN) 202010161896.7

(51) Int. Cl. G03F 1/54; H01L 21/027; G03F 7/20

(52) U.S. Cl. CPC G03F 1/54; G03F 7/70058; G03F 7/201; H01L 21/0274

(57) ABSTRACT

The present disclosure provides a mask, a layout, a lithography system and a lithography process of the lithography system. The mask includes: a base which is transparent to exposure light; and a light-shielding film covering a part of a bottom surface of the base, wherein the light-shielding film forms a main pattern and an assistant pattern, the main pattern is light-shielding to the exposure light and is transferable, and the assistant pattern is light-shielding to the exposure light and is not transferable. The present disclosure can ensure a normal transfer of the main pattern, and reduce light transmittance of the mask.

### CROSS-REFERENCE TO RELATED APPLICATIONS

This application claims the benefit of priority to Chinese patent application No. 202010161896.7, filed on March 10, 2020. The entire contents of this application are hereby incorporated herein by reference.

### TECHNICAL FIELD

The present disclosure relates to the technical field of semiconductor manufacturing, and more particularly to a mask, a layout, a lithography system and a lithography process of the lithography system.

### BACKGROUND

Lithography process is an important step in manufacturing processes of semiconductor devices. Conventional lithography technology applies ultraviolet light with a wavelength of 2000 to 4500 angstroms as exposure light, a mask as an intermediate medium to realize pattern transformation, transfer and processing, and finally a transmission of an image information to a wafer (mainly a silicon wafer) or a dielectric layer.

A lithographic mask includes a pattern master applied in the lithography process, with a mask pattern structure formed by an opaque light-shielding film on a transparent base. The lithographic mask is widely applied in areas involving lithographic processes, such as in manufacturing fields of IC (Integrated Circuit), FPD (Flat Panel Display), and PCB (Printed Circuit Boards).

However, the structure of existing mask needs to be improved.

### SUMMARY

Embodiments of the present disclosure provide a mask, a layout, a lithography system and a lithography process of the lithography system, with which light transmittance of the mask can be reduced while ensuring a normal transfer of the main pattern.

An embodiment of the present disclosure provides a mask, including: a base which is transparent to exposure light; and a light-shielding film covering a part of a bottom surface of the base, wherein the light-shielding film forms a main pattern and an assistant pattern, the main pattern is light-shielding to the exposure light and is transferable, and the assistant pattern is light-shielding to the exposure light and is not transferable.

In some embodiment, the assistant pattern has a linear, dotted, or curved shape.

In some embodiment, the assistant pattern has a width less than a quarter of a wavelength of the exposure light.

In some embodiment, a distance between the assistant pattern and the main pattern is greater than a half of a wavelength of the exposure light.

In some embodiment, the light-shielding film forms one or more than one assistant pattern.

In some embodiment, when the light-shielding film forms more than one assistant pattern, a spacing between adjacent assistant patterns is greater than a third of a wavelength of the exposure light.

Another embodiment of the present disclosure provides a layout of the foregoing mask, including the main pattern and the assistant pattern.

Another embodiment of the present disclosure provides a lithography system, including: a light source for emitting exposure light; a mask for receiving the exposure light and outputting a first processing light carrying an image information of the main pattern; a projection optical system for receiving the first processing light and projecting a second processing light; and a wafer for receiving the second processing light projected by the projection optical system to form a transfer pattern corresponding to the main pattern.

In some embodiment, the wafer comprises a substrate and a photoresist layer covering a surface of the substrate.

Another embodiment of the present disclosure provides a lithography process of the lithography system, including: providing the exposure light with the light source; receiving the exposure light and outputting the first processing light carrying the image information of the main pattern by the mask; receiving the first processing light and projecting the second processing light onto a surface of the wafer by the projection optical system; and receiving the second processing light projected by the projection optical system to form the transfer pattern corresponding to the main pattern by the wafer.

Compared with conventional technologies, embodiments of the present disclosure have following beneficial effects.

The mask includes a base and a light-shielding film. The base is transparent to exposure light, and the light-shielding film covers a part of a bottom surface of the base. Main patterns and assistant patterns are formed with the light-shielding film. Main patterns are light-shielding to the exposure light and are transferable, Main patterns can be transferred to the wafer through an exposure process. Assistant patterns are light-shielding to the exposure light and is not transferable, assistant patterns cannot be transferred to the wafer, and thus the normal transfer process of main patterns is not affected. Furthermore, since assistant patterns are light-shielding to the exposure light, assistant patterns can decrease light transmittance of the exposure light irradiating the mask, thereby avoiding the projection optical system located between the mask and the wafer heating up so fast, which can better protect the projection optical system and prolong the service life of the projection optical system.

### BRIEF DESCRIPTION OF THE DRAWINGS

FIG. 1 is a schematic structural view of a mask according to an embodiment of the present disclosure;

FIG. 2 is a schematic structural view of a main pattern and an assistant pattern according to an embodiment of the present disclosure;

FIG. 3 is a schematic structural view of a main pattern and an assistant pattern according to another embodiment of the present disclosure;

FIG. 4 is a schematic structural view of a main pattern and an assistant pattern according to still another embodiment of the present disclosure;

FIG. 5 is a schematic structural view of a main pattern and an assistant pattern according to yet another embodiment of the present disclosure;

FIG. 6 is a schematic structural view of a lithography system according to an embodiment of the present disclosure; and

FIG. 7 and FIG. 8 are schematic structural views corresponding to each step in a lithography process according to an embodiment of the present disclosure.

### DETAILED DESCRIPTION

As mentioned in the background, the structure of the existing mask still needs to be improved.

A mask can be analyzed like this. The mask includes a base and a light-shielding film, the base is transparent to exposure light, and the light-shielding film covers a part of a bottom surface of the base. Geometric patterns which are light-shielding to the exposure light and are transferable are formed with the light-shielding film. The mask integrally has a high light transmittance to the exposure light, which easily causes the projection optical system located between the mask and the wafer to heat up too quickly.

The inventor has studied the above mask. After creative work, the inventor noticed that by forming a light-shielding film including a main pattern and an assistant pattern, the light transmittance of the mask can be reduced and the affection on the normal transfer of the main pattern can be avoided.

In order to make above objects, features and advantages of the present disclosure more comprehensible, specific embodiments of the present disclosure are described in detail below in connection with accompanying drawings.

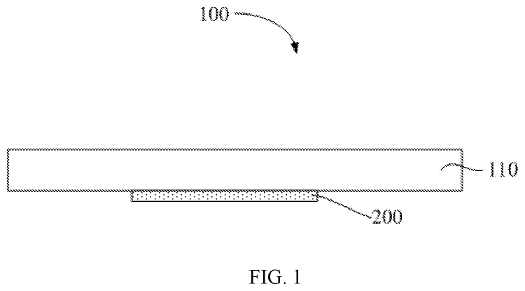

Referring to FIG. 1, a mask 100 includes a base 110 and a light-shielding film 200, and the light-shielding film 200 covers a part of a bottom surface of the base 110.

The base 110 is transparent to exposure light. In some embodiment, the base 110 may be made of transparent glass. Specifically, the base 110 may be made of quartz glass, soda glass or low-expansion glass.

In other embodiments, the base 110 may also be made of a transparent resin.

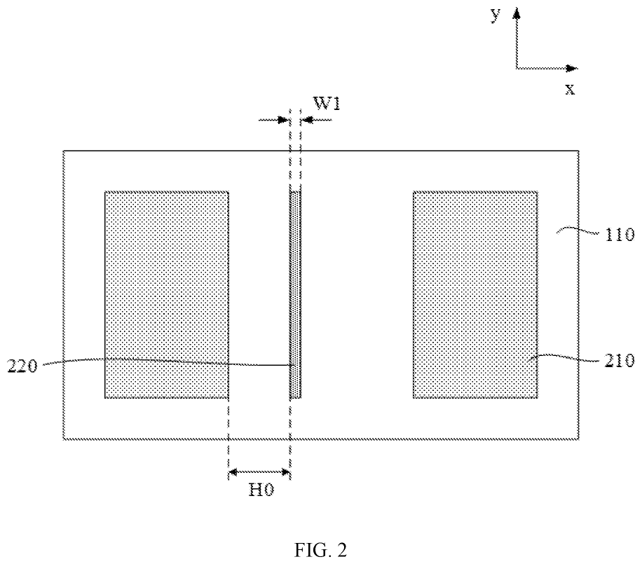

FIG. 2 is a schematic structural view of a main pattern 210 and an assistant pattern 220 according to an embodiment of the present disclosure.

Referring to FIG. 2, in some embodiment, a surface of the base 110 has a rectangle shape. The rectangle includes a first side extending in a first direction x and a second side extending in a second direction y, and a length of the first side is longer than that of the second side.

The light-shielding film 200 has a light-shielding property for the exposure light. In some embodiment, the light-shielding film 200 may be made of chromium. In other embodiments, the light-shielding film 200 may be made of iron oxide, molybdenum silicide, or silicon. In addition, the light-shielding film 200 may also be made of latex.

The light-shielding film 200 forms the main pattern 210 and the assistant pattern 220. The main pattern 210 is light-shielding to the exposure light and is transferable, and the assistant pattern 220 is light-shielding to the exposure light, but not transferable.

The main pattern 210 is a pattern to be transferred. The main pattern 210 has a size that is larger than a resolution of the lithography system, so that the main pattern 210 can be transferred to a wafer.

The assistant pattern 220 is light-shielding to the exposure light, but cannot be transferred. Therefore, the assistant pattern 220 can reduce the light transmittance of the mask 100.

In some embodiment, the assistant pattern 220 may have a linear shape. In other embodiments, the assistant pattern 220 may have a dotted shape or a curved shape. When the assistant pattern 220 has a dotted shape, the assistant pattern 220 may have a circular or irregular shape.

The assistant pattern 220 has a size that is smaller than the resolution of the lithography system, so the assistant pattern 220 cannot be transferred to the wafer, so as to avoid affecting the transfer of the main pattern 210 and ensure the normal transfer of the main pattern 210.

In some embodiment, an extension direction of the assistant pattern 220 is parallel to the second direction Y. In other embodiments, the extension direction of the assistant pattern 220 is parallel to the first direction X, or the extension direction of the assistant pattern 220 is inclined to the first direction X and the second direction Y

A width W1 of the assistant pattern 220 is less than a quarter of a wavelength of the exposure light. If the width of the assistant pattern is too large, the size of the assistant pattern is larger than the resolution of the lithography system, and the assistant pattern can be transferred to the wafer through the exposure process, which will affect the manufacturing quality of the wafer.

In some embodiment, the assistant pattern 220 has a linear shape, and the width W1 of the linear pattern is less than a quarter of the wavelength of the exposure light.

Specifically, in some embodiment, the width W1 of the assistant pattern 220 is 50 nm.

In some embodiment, a distance between the assistant pattern 220 and the main pattern 210 is greater than a half of the wavelength of the exposure light.

In some embodiment, the assistant pattern 220 has a continuous linear shape. In other embodiments, the linear pattern may also include a plurality of separated segments. There may be one or more assistant patterns 220. In some embodiment, there are one assistant pattern 220 and two main patterns 210, and the assistant pattern 220 is arranged between the two main patterns 210.

In other embodiments, when the assistant pattern 220 has a dotted shape, a diameter of the dotted pattern may be taken as the width of the assistant pattern 220.

In some embodiment, as shown in FIG. 2, a distance HO between the main pattern 210 and the assistant pattern 220 is greater than a half of the wavelength of the exposure light. If the distance between the main pattern 210 and the assistant pattern 220 is too small, the assistant pattern 220 may be easily connected to form a combined pattern, and a width of the combined pattern may exceed the resolution of the lithography system, which causes the assistant pattern 220 to be easily transferred to the wafer and affects the normal operation of the lithography process.

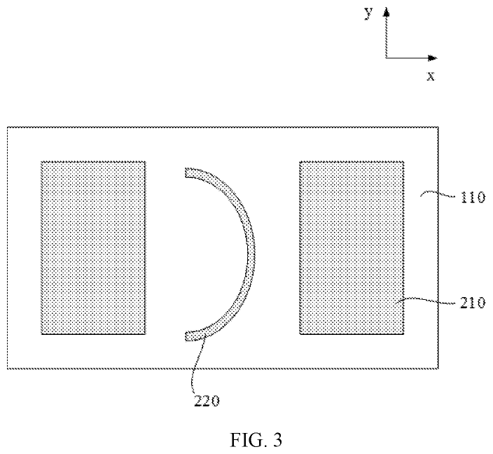

FIG. 3 is a schematic structural view of a main pattern and an assistant pattern according to another embodiment of the present disclosure.

Referring to FIG. 3, in some embodiment, the assistant pattern 220 has a curved shape, and a width of the curved pattern is less than a quarter of the wavelength of the exposure light.

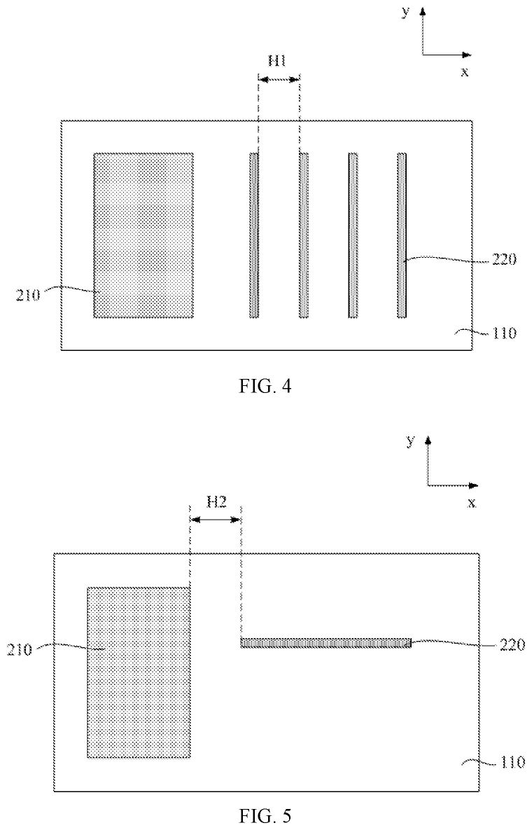

FIG. 4 is a schematic structural view of a main pattern and an assistant pattern according to still another embodiment of the present disclosure.

Referring to FIG. 4, in some embodiment, there are a plurality of assistant patterns 220, and a space is formed between adjacent assistant patterns 220.

In some embodiment, the plurality of assistant patterns 220 are arranged in parallel, and ends of the plurality of assistant patterns 220 are aligned with each other.

In some embodiment, a spacing H1 between adjacent assistant patterns 220 is greater than a third of the wavelength of the exposure light. If the spacing of the adjacent assistant patterns 220 is too small, the adjacent assistant patterns 220 are likely connected to form a combined pattern, and a width of the combined pattern may exceed the resolution of the lithography system, which causes the combined pattern to be easily transferred to the wafer and affects the normal operation of the lithography process.

Specifically, in some embodiment, the spacing H1 between the adjacent assistant patterns 220 is 100 nm.

In some embodiment, a width of each assistant pattern 220 is less than a quarter of the wavelength of the exposure light.

In some embodiment, a distance between the assistant pattern 220 and the main pattern 210 is greater than a half of the wavelength of the exposure light.

In other embodiments, the assistant pattern 220 may also be dispersedly arranged around the main pattern 210.

FIG. 5 is a schematic structural view of a main pattern 210 and an assistant pattern according to yet another embodiment of the present disclosure.

Referring to FIG. 5, in some embodiment, an extension direction of the assistant pattern 220 is parallel to the first direction X.

In some embodiment, a distance H2 between the assistant pattern 220 and the main pattern 210 is greater than or equal to a half of the wavelength of the exposure light. If the distance between the assistant pattern 220 and the main pattern 210 is too small, the assistant pattern 220 may interfere with the normal transfer of the main pattern 210 and affect the lithography quality.

Specifically, in some embodiment, the distance H2 between the assistant pattern 220 and the main pattern 210 is nm.

In some embodiment, a width of the assistant pattern 220 is less than a quarter of the wavelength of the exposure light.

In other embodiments, the assistant pattern includes a plurality of first assistant patterns and a plurality of second assistant patterns. An extension direction of the first assistant patterns is parallel to the first direction x, and an extension direction of the second assistant patterns is parallel to the second direction y.

The present disclosure also provides a layout of the mask 100. The layout includes the main pattern 210 and the assistant pattern 220.

The assistant pattern 220 may have a linear, dotted or curved shape. In this embodiment, the assistant pattern 220 has a linear shape.

The width of the assistant pattern 220 is less than a quarter of the wavelength of the exposure light. In some embodiment, the width of the assistant pattern 220 is 50 nm.

The distance between the assistant pattern 220 and the main pattern 210 is greater than a half of the wavelength of the exposure light. In some embodiment, the distance between the assistant pattern 220 and the main pattern 210 is 150 nm.

In some embodiment, there are a plurality of assistant patterns 220, and a spacing is formed between adjacent assistant patterns 220.

In some embodiment, the spacing between the adjacent assistant patterns 220 is greater than a third of the wavelength of the exposure light. Specifically, the spacing between the adjacent assistant patterns 220 is 100 nm.

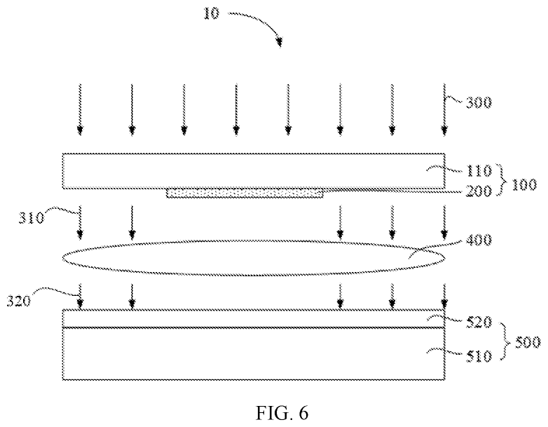

FIG. 6 is a schematic structural view of a lithography system 10 according to an embodiment of the present disclosure.

Referring to FIG. 6, in some embodiment, the lithography system 10 includes: a light source (not shown in the figure) for emitting exposure light 300; the mask 100 for receiving the exposure light 300, and outputting a first processing light 310 carrying an image information of the main pattern 210 (referring to FIG. 2); a projection optical system 400 for receiving the first processing light 310 and projecting a second processing light 320; and a wafer 500 for receiving the second processing light 320 projected by the projection optical system 400 to form a transfer pattern corresponding to the main pattern 210.

In some embodiment, the wafer 500 includes a substrate 510 and a photoresist layer 520 covering a surface of the substrate 510. The photoresist layer 520 forms the transfer pattern corresponding to the main pattern 210.

Another embodiment of the present disclosure also provides a lithography process of the lithography system 10.

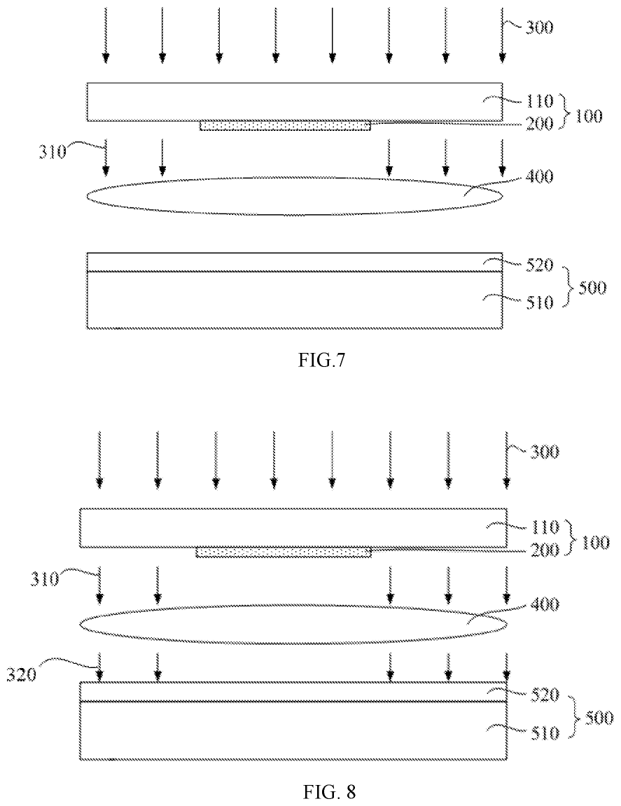

Referring to FIG. 7, the light source emits the exposure light 300, and the mask 100 receives the exposure light 300 and outputs the first processing light 310 carrying the image information of the main pattern 210.

In some embodiment, the exposure light 300 may be ultraviolet light. A wavelength of the exposure light 300 emitted from an ArF exposure machine is 193 nm, the wavelength of the exposure light 300 emitted from a KrF exposure machine is 248 nm, and the wavelength of the exposure light 300 emitted from an I-line exposure machine is 365 nm. In this embodiment, the exposure light 300 is emitted from the KrF exposure machine.

Referring to FIG. 8, the projection optical system 400 receives the first processing light 310 and projects the second processing light 320 onto a surface of the wafer 500. The wafer 500 receives the second processing light 320 projected by the projection optical system 400 to form the transfer pattern corresponding to the main pattern 210.

In some embodiment, the wafer 500 includes the substrate 510 and the photoresist layer 520 covering the surface of the substrate 510.

The photoresist layer 520 receives the second processing light 320 projected by the projection optical system 400 to form the transfer pattern corresponding to the main pattern 210.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A mask, comprising:
a base which is transparent to exposure light; and
a light-shielding film covering a part of a bottom surface of the base, wherein the light-shielding film forms a main pattern and an assistant pattern, the main pattern is light-shielding to the exposure light and is transferable, and the assistant pattern is light-shielding to the exposure light and is not transferable.

2. The mask according to claim 1, wherein the assistant pattern has a linear, dotted, or curved shape.

3. The mask according to claim 2, wherein the assistant pattern has a width less than a quarter of a wavelength of the exposure light.

4. The mask according to claim 2, wherein a distance between the assistant pattern and the main pattern is greater than a half of a wavelength of the exposure light.

5. The mask according to claim 2, wherein the light-shielding film forms one or more than one assistant pattern.

6. The mask according to claim 5, wherein when the light-shielding film forms more than one assistant pattern, a spacing between adjacent assistant patterns is greater than a third of a wavelength of the exposure light.

7. A layout of the mask according to claim 1, comprising the main pattern and the assistant pattern.

8. A lithography system, comprising:
a light source for emitting exposure light;
the mask according to claim 1, for receiving the exposure light and outputting a first processing light carrying an image information of the main pattern;
a projection optical system for receiving the first processing light and projecting a second processing light; and
a wafer for receiving the second processing light projected by the projection optical system to form a transfer pattern corresponding to the main pattern.

9. The lithography system according to claim 8, wherein the wafer comprises a substrate and a photoresist layer covering a surface of the substrate.

10. A lithography process of the lithography system according to claim 8, comprising:
providing the exposure light with the light source;
receiving the exposure light and outputting the first processing light carrying the image information of the main pattern by the mask;
receiving the first processing light and projecting the second processing light onto a surface of the wafer by the projection optical system; and
receiving the second processing light projected by the projection optical system to form the transfer pattern corresponding to the main pattern by the wafer.
